(19) United States
(12) Patent Application Publication
(10) Pub. No.: US 2007/0001721 A1
(43) Pub. Date: Jan. 4, 2007

(54) POWER-ON RESET CIRCUIT

(76) Inventors: Chi-Yang CHEN, Hsinchu County (TW); Rong-Chin LEE, Pingtung County (TW)

Correspondence Address: NORTH AMERICA INTELLECTUAL PROPERTY CORPORATION, P.O. BOX 506, MERRIFIELD, VA, 22116, US

(21) Appl. No.: 11/160,635

(22) Filed: Jul. 1, 2005

(51) Int. Cl. H03L 7/00

(52) U.S. Cl. 327/143

(57) ABSTRACT

A power-on reset circuit has a reset starting circuit, a reset finishing circuit, and a latch circuit. The reset starting circuit generates a reset starting signal in response to a power voltage. When the power voltage reaches a predetermined reset finishing voltage, the reset finishing circuit generates a reset finishing signal. The latch circuit generates a power-on reset signal having a first state and a second state. In response to the reset starting signal, the latch circuit causes the power-on reset signal to transition to the first state. In response to the reset finishing signal, the latch circuit causes the power-on reset signal to transition to the second state.

### BACKGROUND OF THE INVENTION

1. Field of the Invention

The present invention relates to a power-on reset circuit and, more particularly, to a power-on reset circuit capable of accurately setting a reset finishing voltage.

2. Description of the Prior Art

Most integrated circuit chips usually include a plenty of transistors and basic logic units. After the power is turned on, the power voltage is rising from zero to a predetermined stable value at which the integrated circuit chip is operated normally. In order to avoid any uncertainty with initial states of the transistors and logic units in the integrated circuit chip, it is necessary before the power voltage reaches the stable value to have performed a reset operation phase with respect to the transistors and logic units. For this reason, a power-on reset circuit is designed for providing a power-on reset signal to control the starting as well as finishing of the reset operation phase before the power voltage reaches the stable value, ensuring that the integrated circuit chip has a certain initial state.

Typically, one integrated circuit chip is designed to operate in response to several different stable values of the power voltage. No matter what stable value the power voltage will reaches, the reset operation phase for the integrated circuit chip is required to be finished at a specified value (hereinafter referred to as a reset finishing voltage). That is, the initial state of the integrated circuit chip must be reset at least before the power voltage reaches the specification-required reset finishing voltage so as to ensure a normal operation. Unfortunately, conventional power-on reset circuits fail to satisfy this requirement.

### SUMMARY OF THE INVENTION

An object of the present invention is to provide a power-on reset circuit capable of accurately setting and adjusting a reset finishing voltage.

A power-on reset circuit according to the present invention includes a reset starting circuit, a reset finishing circuit, and a latch circuit. The reset starting circuit generates a reset starting signal in response to a power voltage. When the power voltage reaches a predetermined reset finishing voltage, the reset finishing circuit generates a reset finishing signal. The latch circuit generates a power-on reset signal having a first state and a second state. In response to the reset starting signal, the latch circuit causes the power-on reset signal to transition to the first state. In response to the reset finishing signal, the latch circuit causes the power-on reset signal to transition to the second state.

The reset finishing circuit includes a voltage detection unit, a reference voltage generation unit, and a voltage comparison unit. The voltage detection unit generates a detection voltage representative of the power voltage. The reference voltage generation unit generates a reference voltage in association with the predetermined reset finishing voltage. The voltage comparison unit compares the detection voltage and the reference voltage such that the voltage comparison unit is triggered to generate the reset finishing signal when the detection voltage reaches the reference voltage.

In one embodiment, the latch circuit enables the reset finishing circuit in response to the reset starting signal. In another embodiment, a delay circuit is coupled between the latch circuit and the reset finishing circuit for enabling the reset finishing circuit by a delay time after the latch circuit causes the power-on reset signal to transition to the first state.

### BRIEF DESCRIPTION OF THE DRAWINGS

The above-mentioned and other objects, features, and advantages of the present invention will become apparent with reference to the following descriptions and accompanying drawings, wherein:

FIG. 1 is a detailed circuit diagram showing a power-on reset circuit according to a first embodiment of the present invention;

FIG. 2 is a waveform timing chart showing an operation of a power-on reset circuit according to a first embodiment of the present invention;

FIG. 3 is a detailed circuit diagram showing a power-on reset circuit according to a second embodiment of the present invention; and

FIG. 4 is a waveform timing chart showing an operation of a power-on reset circuit according to a second embodiment of the present invention.

### DETAILED DESCRIPTION

The preferred embodiments according to the present invention will be described in detail with reference to the drawings.

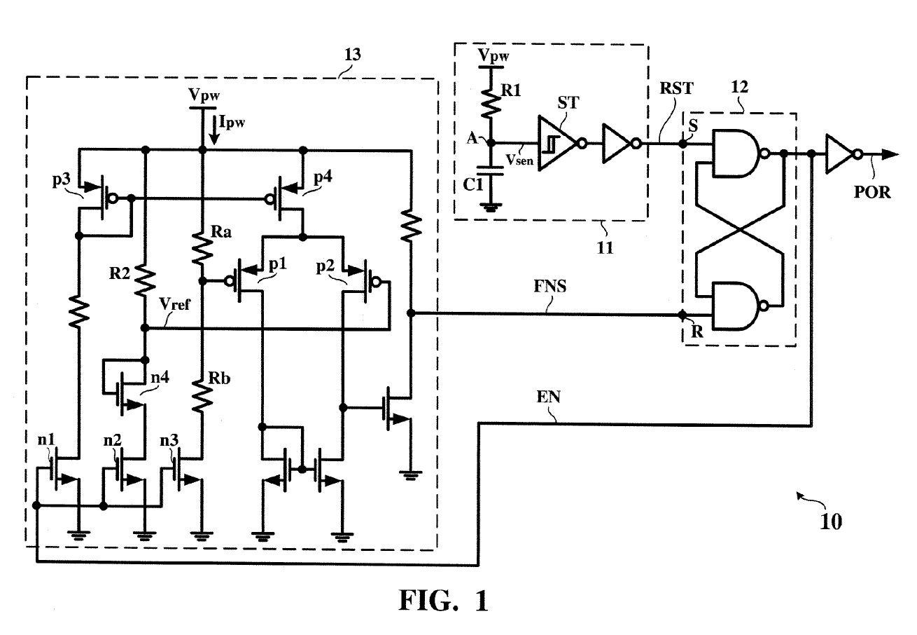

FIG. 1 is a detailed circuit diagram showing a power-on reset circuit 10 according to a first embodiment of the present invention. Referring to FIG. 1, the power-on reset circuit 10 includes a reset starting circuit 11, a latch circuit 12, and a reset finishing circuit 13. The reset starting circuit 11 generates and applies a reset starting signal RST to the latch circuit 12. The reset finishing circuit 12 generates and applies a reset finishing signal FNS to the latch circuit 12. The reset finishing circuit 13 is activated by an enable signal EN in feedback from an output terminal of the latch circuit 12. In response to the reset starting signal RST and the reset finishing signal FNS, the latch circuit 12 determines states of a power-on reset signal POR. The power-on reset signal POR is applied to other circuits (not shown) of the integrated circuit chip for performing the reset operation phase.

The reset starting circuit 11 primarily has a voltage detection unit and a trigger unit. The voltage detection unit generates a detection voltage Vₛₑₙ representative of the power voltage V_{pw}. The voltage detection unit may be implemented by a resistor R1 and a capacitor C1 coupled in series to form a capacitive voltage divider. When the power voltage V_{pw} starts rising from zero, a voltage division of the power voltage V_{pw} is provided at the connecting node A between the resistor R1 and the capacitor C1, which is serving as the detection voltage Vₛₑₙ. The trigger unit may be implemented by a Schmidt trigger ST connected in series with an inverter. The Schmidt trigger ST may be considered as an inverter with a hysteresis function for preventing the noise on the detection voltage Vₛₑₙ from causing an erroneous trigger event. Once the power voltage V_{pw} reaches an appropriate voltage to trigger the Schmidt trigger ST, the reset starting signal RST from the reset starting circuit 11 applies a rising edge to a first input terminal S of the latch circuit 12. In response to the rising edge of the reset starting signal RST, the latch circuit 12 causes the power-on reset signal POR to transition to a low level state for starting the reset operation phase. In the embodiment shown in FIG. 1, the latch circuit 12 is mainly formed by two cross-coupled NAND logic gates, but the present invention is not limited to this and the latch circuit 12 may be implemented by other logic gates as long as the same logic function can be executed.

The reset finishing circuit 13 primarily has a switch unit, a voltage detection unit, a reference voltage generation unit, and a voltage comparison unit. The switch unit consists of three transistor switches n1 to n3 for respectively controlling current paths of the voltage comparison unit, the reference voltage unit, and the voltage detection unit. When the enable signal EN is at a low level state, all of the three transistor switches n1 to n3 are turned off, resulting in no current paths formed between the power voltage V_{pw} and the ground potential. In other words, through the use of the switch unit, the reset finishing circuit 13 is activated under the control of the enable signal EN at a high level state. The reference voltage generation unit may be implemented by a resistor R2 and a diode-coupled transistor n4, connected in series between the power voltage V_{pw} and the ground potential, for generating a reference voltage V_{ref}, which is therefore approximately equal to a diode drop. The transistor switch n2 controls the current path of the reference voltage generation unit. The voltage detection unit may be implemented by a resistive voltage divider of two resistors Ra and Rb, connected in series between the power voltage V_{pw} and the ground potential, for generating a voltage division [Rb/(Ra+Rb)]*V_{pw}. The transistor switch n3 controls the current path of the voltage detection unit.

The voltage comparison unit primarily has a differential amplifying pair of transistors p1 and p2, which are driven by a current mirror made up of transistors p3 and p4. The voltage division [Rb/(Ra+Rb)]*V_{pw} from the voltage detection unit is applied to a gate electrode of the transistor p1 while the reference voltage V_{ref} from the reference voltage generation unit is applied to a gate electrode of the transistor p2. As a result, the voltage comparison unit determines the states of the reset finishing signal FNS based on the comparison between the voltage division [Rb/(Ra+Rb)]*V_{pw} and the reference voltage V_{ref}. When the voltage division [Rb/(Ra+Rb)]*V_{pw} is lower than the reference voltage V_{ref}, the reset finishing signal FNS is generated at the high level state. Once the voltage division [Rb/(Ra+Rb)]*V_{pw} reaches the reference voltage V_{ref}, the voltage comparison unit is triggered to make the reset finishing signal FNS fall down to a low level state. The reset finishing signal FNS is applied to a second input terminal R of the latch circuit 12. In response to the falling edge of the reset finishing signal FNS, the power-on reset signal POR transitions to a high level state for terminating the reset operation phase.

Therefore, the reset operation phase can be finished in such an accurately controllable manner as setting the value of the reference voltage V_{ref} since the reset finishing voltage is calculated in accordance with the expression [(Ra+Rb)/Rb]*V_{ref}. In other words, when the power voltage V_{pw} reaches the thus-designed reset finishing voltage, the power-on reset signal POR is triggered to terminate the reset operation phase and make the integrated circuit chip be ready for normal operations.

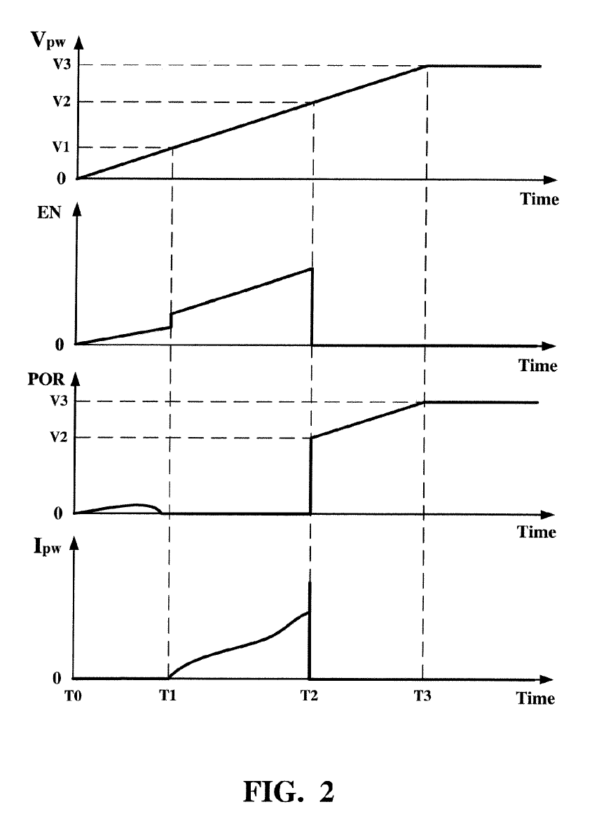

FIG. 2 is a waveform timing chart showing an operation of a power-on reset circuit 10 according to a first embodiment of the present invention. Referring to FIG. 2, assumed is that the power voltage V_{pw} starts rising from zero at time T0, reaches a first voltage VI at time Ti, reaches a second voltage V2 at time T2, and reaches a third voltage V3 at time T3 and then remains stable. When the power voltage V_{pw} is lower than a threshold voltage of a transistor, i.e. about 0.7 volts, the enable signal EN and the power-on reset signal POR slightly goes up along with the power voltage V_{pw} because of parasitic capacitances in the circuitry. During this period no significant consumption of the power current I_{pw} occurs since the transistors are kept non-conductive. At the time T1, the enable signal EN jumps up to a high level state and the power-on reset signal POR falls down to a low level state because the power voltage V_{pw} reaches the first voltage VI to trigger the Schmidt trigger ST. Therefore, the time T1 indicates the beginning of the reset operation phase.

From the time T1 to T2, the enable signal EN goes higher as following the rising in the power voltage V_{pw} while the power-on reset signal POR is fixed at the ground potential. During this period the power current I_{pw} starts being remarkably consumed because the current paths of the reset finishing circuit 13 are all turned on by the enable signal EN. At the time T2, the power-on reset signal POR jumps up to the high level state for terminating the reset operation phase because the power voltage V_{pw} reaches the second voltage V2, i.e. the reset finishing voltage, to trigger the voltage comparison unit of the reset finishing circuit 13. Additionally, the enable signal EN falls down to the low level state at the same time for blocking all of the current paths in the reset finishing circuit 13. Therefore, the consumption of the power current I_{pw} is ceased after the time T2, and the power-on reset signal POR goes higher to a stable value as flowing the power voltage V_{pw}.

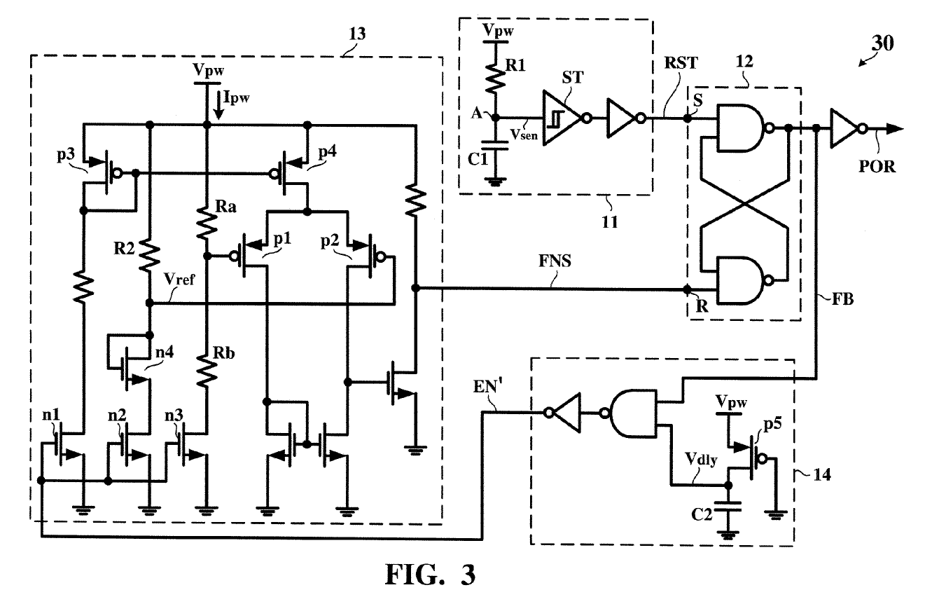

FIG. 3 is a detailed circuit diagram showing a power-on reset circuit 30 according to a second embodiment of the present invention. In FIG. 3, for simplicity, like reference numerals have been used to identify like components illustrated in FIG. 1 and previously described, with additional detail being shown in the timing and control portion of the circuit relevant to the second embodiment. The second embodiment is different from the first embodiment in that the second embodiment of FIG. 3 further includes a delay circuit 14 for waiting a delay time T_{dly} after the latch circuit 12 is triggered by the reset starting signal RST to enable the reset finishing circuit 13, thereby saving the consumption of the power current I_{pw}. Specifically, the delay circuit 14 primarily includes a delay voltage generation unit and a logic control unit. The delay voltage generation unit may be implemented by a transistor p5 and a capacitor C2 connected in series between the power voltage V_{pw} and the ground potential, for generating a delay voltage V_{dly}. After the transistor p5 is turned on by the rise in the power voltage V_{pw}, the capacitor C2 starts being charged and therefore provides the delay voltage V_{dly}. The logic control unit is implemented by a NAND logic gate for receiving the feedback signal FB from the latch circuit 12 and the delay voltage V_{dly}. Under the control of the delay circuit 14, the enable signal EN′ of the second embodiment is prevented from rising up although the feedback signal FB has changed to the high level state immediately after the Schmidt trigger ST is triggered. Until the delay voltage V_{dly} becomes large enough for being considered as the high level state by the NAND logic gate of the logic control unit, the enable signal EN′ of the second embodiment is triggered to become the high level state. It should be noted that the delay circuit 14 may be implemented by other types of analog timers or digital counters as long as the desired delay time T_{dly} is provided and controlled.

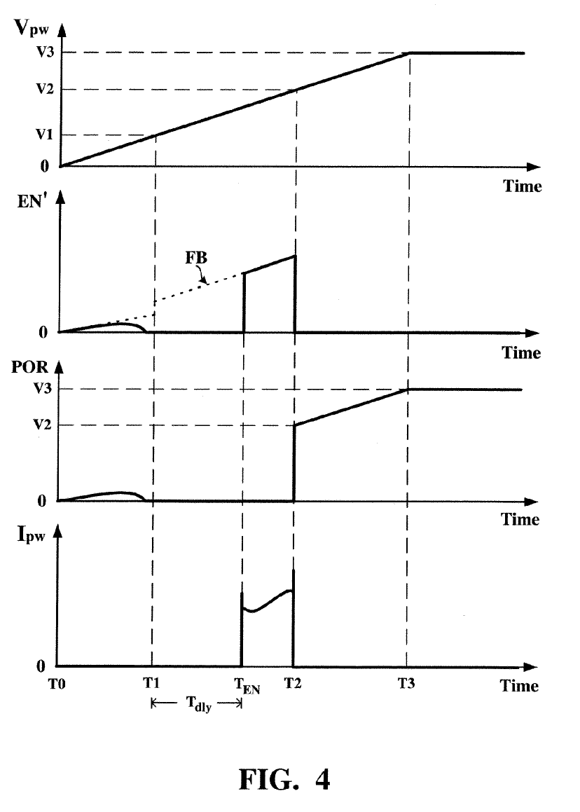

FIG. 4 is a waveform timing chart showing an operation of a power-on reset circuit 30 according to a second embodiment of the present invention. Referring to FIG. 4, the feedback signal of the second embodiment is identical to the enable signal of the first embodiment since both of them are the output signal of the latch circuit 12. During the delay time T_{dly} from the time T1 to T_{EN}, although the power-on reset signal POR has already transitioned to the ground potential for starting the reset operation phase, the enable signal EN′ of the second embodiment is still at the low level sate and therefore suppresses the consumption of the power current I_{pw}. Only from the time T_{EN} does the enable signal EN′ of the second embodiment transition to the high level state to activate the reset finishing circuit 13. As a result, the power current I_{pw} is remarkably consumed from the time T_{EN} to time T2.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A power-on reset circuit comprising:
a reset starting circuit for generating a reset starting signal in response to a power voltage;
a reset finishing circuit for generating a reset finishing signal when the power voltage reaches a predetermined reset finishing voltage; and
a latch circuit for generating a power-on reset signal having a first state and a second state, wherein:
in response to the reset starting signal, the latch circuit causes the power-on reset signal to transition to the first state, and
in response to the reset finishing signal, the latch circuit causes the power-on reset signal to transition to the second state.

2. The circuit according to claim 1, wherein:
the first state of the power-on reset signal is substantially equal to a ground potential, and
the second state of the power-on reset signal is substantially equal to the power voltage.

3. The circuit according to claim 1, wherein:
the latch circuit enables the reset finishing circuit in response to the reset starting signal.

4. The circuit according to claim 1, further comprising:
a delay circuit coupled between the latch circuit and the reset finishing circuit for enabling the reset finishing circuit by a delay time after the latch circuit causes the power-on reset signal to transition to the first state.

5. The circuit according to claim 1, wherein:
the reset starting circuit comprises:
a voltage detection unit for generating a detection voltage representative of the power voltage, and
a trigger unit for generating the reset starting signal when triggered by the detection voltage.

6. The circuit according to claim 1, wherein:
the reset finishing circuit comprises:
a voltage detection unit for generating a detection voltage representative of the power voltage,
a reference voltage generation unit for generating a reference voltage in association with the predetermined reset finishing voltage, and
a voltage comparison unit for comparing the detection voltage and the reference voltage such that the voltage comparison unit is triggered to generate the reset finishing signal when the detection voltage reaches the reference voltage.

7. The circuit according to claim 6, wherein:
the reset finishing circuit further comprises:
a switch unit, through which the latch circuit turns on current paths of the voltage detection unit, the reference voltage generation unit, and the voltage comparison unit.

8. A power-on reset circuit for generating a power-on reset signal in response to a power voltage, comprising:
a first circuit for causing the power-on reset signal to transition to a first state when the power voltage reaches a first voltage rising from zero;
a second circuit for generating a predetermined second voltage;
a third circuit for generating a detection voltage representative of the power voltage; and
a fourth circuit for comparing the detection voltage and the second voltage so as to causing the power-on reset signal to transition to a second state when the detection voltage reaches the predetermined second voltage.

9. The circuit according to claim 8, further comprising:
a fifth circuit for setting a delay time such that the second, the third, and the fourth circuits are enabled by the delay time after the power voltage reaches the first voltage.

10. The circuit according to claim 8, wherein:
the first state of the power-on reset signal is substantially equal to a ground potential, and
the second state of the power-on reset signal is substantially equal to the power voltage.
